(19) United States
(12) Patent Application Publication
(10) Pub. No.: US 2009/0155626 A1
(43) Pub. Date: Jun. 18, 2009

(54) MAGNETIC RECORDING MEDIUM

(75) Inventor: Ryoichi Mukai, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/330,971

(22) Filed: Dec. 9, 2008

(30) Foreign Application Priority Data
Dec. 14, 2007 (JP) 2007323939

(51) Int. Cl. G11B 5/667; C23C 14/34

(52) U.S. Cl. 428/810; 428/827; 204/192.1

(57) ABSTRACT

According to an aspect of an embodiment, a magnetic recording medium includes: a soft magnetic underlayer disposed on a substrate; a foundation layer on the soft magnetic underlayer, the foundation layer including a plurality of Ru crystal grains isolated from each other at an upper portion of the foundation layer; a first magnetic layer including a plurality of magnetic crystal grains on the plurality of the Ru crystal grains of the foundation layer; and a second magnetic layer disposed on the plurality of magnetic crystal grains of the first magnetic layer, the second magnetic layer including a plurality of magnetic crystal grains having axes of easy magnetization in the direction perpendicular to the major surface of the substrate and nonmagnetic materials interposed between the crystal grains, the magnetic crystal grains of the first magnetic layer having a smaller grain size than those of the second magnetic layer.

### CROSS REFERENCE TO RELATED APPLICATIONS

This application is based upon and claims the benefit of priority from the prior Japanese Patent Application No. 2007-323939 filed on Dec. 14, 2007, the entire content of which is incorporated herein by reference.

### BACKGROUND

1. Field

This art relates to a magnetic recording medium for recording information thereon and a method for manufacturing the magnetic recording medium.

2. Description of the Related Art

Hard disk drive devices are digital signal recording devices, wherein a memory unit price per bit is inexpensive and a higher capacity can be achieved and, in recent years, large amounts of hard disk drive devices have been used for personal computers and the like. Furthermore, since a ubiquitous age has come, it is expected that a demand as a recording device increases dramatically while use in digital AV-associated devices serves as an engine. Therefore, further increase in recording capacity of a hard disk drive device is required to record video signals.

In many cases, hard disk drive devices are incorporated into ordinary household products. Consequently, it becomes also necessary to further reduce the memory unit price in addition to such an increase in recording capacity. In order to reduce the memory unit price, a reduction in the number of components constituting a hard disk drive device is an effective means. Specifically, the recording capacity can be increased by increasing the recording density of a magnetic recording medium (magnetic disk) without increasing the number of required magnetic recording media. Furthermore, if a dramatic increase in recording capacity is realized, the number of required magnetic recording media can be reduced while the recording capacity is allowed to increase and, in addition, the number of magnetic heads to be used can be reduced. As a result, the memory unit price can be reduced dramatically.

Under the circumstances, an increase in recording density of the magnetic recording medium becomes an issue to be addressed, and it is required to achieve a higher S/N ratio (ratio of output to noise) on the basis of resolution enhancement (increase in output) and noise reduction. In order to realize this, size reduction of magnetic particles constituting a magnetic recording layer, equalization of particle sizes, and magnetic isolation have been attempted.

By the way, in production of the perpendicular magnetic recording medium, previously, a CoCr based alloy film has been formed by a sputtering method in combination with substrate heating so as to serve as a magnetic recording layer. Regarding this CoCr based alloy film, nonmagnetic Cr is segregated at crystal grain boundaries of CoCr based alloy magnetic crystal grains and, thereby, magnetic isolation between magnetic grains is intended. However, in the perpendicular magnetic recording medium, it is necessary that an amorphous soft magnetic layer is disposed as a lower layer in order to suppress an occurrence of spike noise resulting from formation of magnetic domains. Since this soft magnetic layer is maintained to be amorphous, an issue occurs in that a substrate heat treatment required for Cr segregation cannot be conducted in formation of the magnetic layer.

Consequently, instead of a Cr segregation technology by using a heat treatment, a perpendicular magnetic recording medium has been developed, in which a magnetic film produced by adding SiO₂ to a CoCr based alloy is used as a magnetic recording layer. In this magnetic film, CoCr based alloy magnetic crystal grains (for example, CoCrPt) are mutually spatially separated by an oxide (for example, SiO₂) which is a nonmagnetic material, and the crystal grains are magnetically isolated.

In order to form a magnetic recording layer having a structure (granular structure) in which magnetic grains are surrounded by a nonmagnetic material, e.g. SiO₂, a thick ruthenium (Ru) film in the form of a continuous film is disposed just below the magnetic recording layer. In this thick Ru film, a shape of groove having an appropriate depth is formed at a Ru crystal grain boundary portion and, thereby, a magnetic recording layer having a structure in which magnetic crystal grains formed on Ru crystal grains are mutually spatially separated by SiO₂ can be formed.

However, if the film thickness of a Ru foundation film interposed between the magnetic recording layer and an underlayer is large, it is necessary to increase a magnetizing force of a write head required for writing, and there is an issue in that blurring occurs in writing. Furthermore, if the film thickness of the Ru foundation film increases, crystal grain sizes are enlarged.

In order to solve the above-described issues, a method is proposed, wherein a Ru foundation layer serving as a substrate of a recording layer, which is a magnetic film, is allowed to have a gap structure in which Ru crystal grains are mutually spatially separated by gap portions (refer to Japanese Laid-open Patent Publication No. 2005-353256, for example).

### SUMMARY

According to an aspect of an embodiment, a magnetic recording medium includes: a substrate; a soft magnetic underlayer disposed on the substrate; a foundation layer on the soft magnetic underlayer, the foundation layer including a plurality of Ru crystal grains isolated from each other at an upper portion of the foundation layer; a first magnetic layer including a plurality of magnetic crystal grains on the plurality of the Ru crystal grains of the foundation layer; and a second magnetic layer disposed on the plurality of magnetic crystal grains of the first magnetic layer, the second magnetic layer including a plurality of magnetic crystal grains having axes of easy magnetization in the direction perpendicular to the major surface of the substrate and nonmagnetic materials interposed between the crystal grains, the magnetic crystal grains of the first magnetic layer having a smaller grain size than those of the second magnetic layer.

### BRIEF DESCRIPTION OF THE DRAWINGS

FIG. 1 is a partial sectional view of a perpendicular magnetic recording medium according to a first embodiment;

FIG. 2 is a graph showing the Δθ₅₀ of the (001) faces of core crystal grains of an ultrathin magnetic layer, where the thickness of the ultrathin magnetic layer is changed;

FIG. 3 is a graph showing the Δθ₅₀ of the (001) faces of the magnetic crystal grains of a recording layer, where the thickness of an ultrathin magnetic layer is changed;

FIG. 4 is a graph showing the saturation magnetic field Hs of a recording layer, where the thickness of an ultrathin magnetic layer is changed;

FIG. 5 is a graph showing the dispersion ΔHs of the saturation magnetic field Hs of a recording layer, where the thickness of an ultrathin magnetic layer is changed;

FIG. 6 is a partial sectional view of a perpendicular magnetic recording medium according to a second embodiment;

FIG. 7 is an internal plan view of a hard disk device incorporated with the perpendicular magnetic recording medium according to the first or second embodiment; and

FIG. 8 is a partial sectional view of a perpendicular magnetic recording medium according to a comparative embodiment.

### DESCRIPTION OF THE PREFERRED EMBODIMENTS

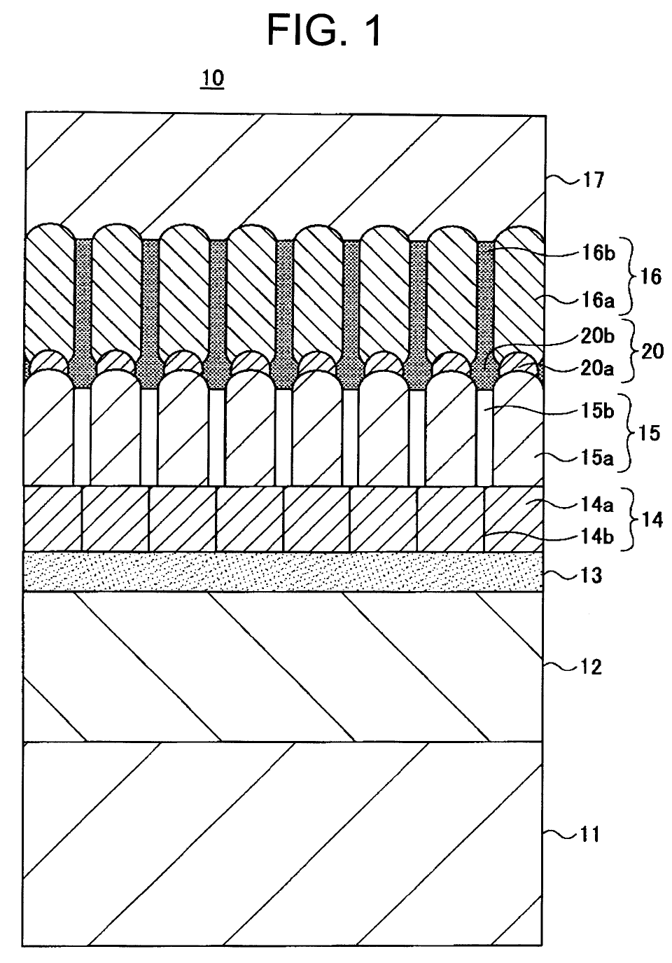

A first embodiment will be described with reference to the drawings. FIG. 1 is a partial sectional view of a perpendicular magnetic recording medium 10 according to the first embodiment.

The perpendicular magnetic recording medium 10 has a structure in which a soft magnetic underlayer 12, an orientation control layer 13, a first foundation layer 14, a second foundation layer 15, an ultrathin magnetic layer 20, a recording layer 16, and a cap layer 17 are disposed sequentially on a substrate 11. In the present embodiment, the ultrathin magnetic layer 20 serving as a first magnetic layer is disposed on the second foundation layer 15. The recording layer 16 serving as a second magnetic layer is disposed on the ultrathin magnetic layer 20. The crystal orientation dispersion of the recording layer 16 serving as the second magnetic layer is improved, that is, lowered by disposition of the ultrathin magnetic layer 20 and, thereby, the magnetization characteristics of individual crystal grains 16b become uniform.

The substrate 11 is any substrate, for example, a plastic substrate, a glass substrate, a Si substrate, a ceramic substrate, and a heat-resistant resin substrate, which can be appropriately used as a substrate of magnetic recording medium. In the present embodiment, the glass disk substrate is used.

The soft magnetic underlayer (SUL) 12 is formed from any amorphous or microcrystalline soft magnetic material, and the film thickness thereof is about 50 nm to 2 μm. The soft magnetic underlayer 12 may have a single-layer structure or a layered structure. The soft magnetic underlayer 12 is to absorb a magnetic flux from a recording head, and it is preferable that the value of product of saturation magnetic flux density Bs and film thickness is large. It is preferable that FeSi, FeAlSi, FeTaC, CoZrNb, CoCrNb, NiFeNb, Co, and the like are used as the soft magnetic material having a saturation magnetic flux density Bs of 1.0 T or more.

The film thickness of the orientation control layer 13 is about 1.0 nm to 10 nm. The orientation control layer 13 has functions of orienting c axes (easy magnetization axes) of crystal grains of the first and second foundation layers 14 and 15 disposed on the orientation control layer 13 toward the film thickness direction and distribute the crystal grains of the first and second foundation layers 14 and 15 in an in-plane direction of the substrate uniformly. The orientation control layer 13 is formed from at least one type of material selected from, for example, amorphous Ta, Ti, C, Mo, W, Re, Os, Hf, Mg, Pt, and alloys thereof. Preferably, the film thickness of the orientation control layer 13 is set within the range of 2.0 nm to 5.0 nm from the viewpoint of the need for reduction of the distance between the soft magnetic underlayer 12 and the recording layer 16 and ensuring of an function of controlling the crystal orientation of a layer disposed on the orientation control layer 13.

The first foundation layer 14 disposed on the orientation control layer 13 is formed as a continuous polycrystalline film of ruthenium (Ru) or a Ru alloy having a hexagonal closest packing (hcp) crystal structure and contains crystal grains 14a and crystal grain boundaries 14b. The first foundation layer 14 is a continuous polycrystalline film in which crystal grains 14a are mutually bonded with crystal grain boundaries 14b and has good crystallinity. The crystal orientation of the (001) face of the first foundation layer 14 is directed toward a direction perpendicular to the substrate 11. The first foundation layer 14 is not necessarily disposed. However, it is desirable that the first foundation layer 14 is disposed just below the second foundation layer 15 in order to improve the crystallinity and the orientation property of the second foundation layer 15 and the recording layer 16 disposed on the first foundation layer 14.

The second foundation layer 15 is disposed on the first foundation layer 14. The second foundation layer 15 contains crystal grains 15a extending in a direction perpendicular to the substrate 11 and gap portions 15b separating the crystal grains 15a from each other in an in-plane direction. The crystal grain 15a is preferably formed of Ru or a Ru alloy.

In the present embodiment, the ultrathin magnetic layer 20 serving as the first magnetic layer is disposed on the second foundation layer 15. The ultrathin magnetic layer 20 contains core crystal grains 20a which are fine crystal grains disposed on individual isolated crystal grains of the second foundation layer 15 and nonmagnetic materials 20b surrounding the core crystal grains 20a. It is preferable that a Co based alloy, e.g. CoCr, CoCrTa, CoPt, CoCrPt, or CoCrPt-M, is used as the material for the core crystal grains 20a, as in the second magnetic layer described later. It is preferable that the material for the core crystal grains 20a is the same as that for the magnetic crystal grains 16a of the second magnetic layer in consideration of simplification of a film formation step, although not limited to this. Different materials may be selected and used appropriately in accordance with characteristics required. It is preferable that the grain sizes of the core crystal grains 20a are smaller than the grain sizes of the above-described crystal grains 15a. At least one core crystal grains 20a may be disposed on each crystal grain 15a of the second foundation layer 15. It is preferable that a core crystal grain 20a may be disposed on each crystal grain 15a of the second foundation layer 15.

It is a new finding of the present inventors that the crystal orientation dispersion of the recording layer 16 is suppressed and reduced by disposition of the core crystal grains 20a which are fine crystal grains, as described above, and an effect which is not obtained on the basis of a known structure can be exerted. Reduction in the crystal orientation dispersion can align the orientation of the (001) faces of a plurality of magnetic crystal grains 16a in the recording layer 16. In this manner, the magnetic crystal grains 16a have uniform magnetization characteristics and, thereby, a perpendicular magnetic recording medium having a high S/N ratio can be obtained.

The recording layer 16 is disposed as the second magnetic layer on the ultrathin magnetic layer 20. The recording layer 16 has a film thickness of, for example, 6 nm to 20 nm and contains columnar magnetic crystal grains 16a extending perpendicularly to the substrate 11 and nonmagnetic materials 16b surrounding the magnetic crystal grains 16a so as to separate the magnetic crystal grains 16a from each other in an in-plane direction. The magnetic crystal grains 16a are crystal grains grown on the fine crystal grains 20a of the layer disposed thereunder. The grain sizes of the magnetic crystal grains 16a are larger than the grain sizes of the above-described fine crystal grains 20a. That is, the fine crystal grains 20a having grain sizes smaller than the grain sizes of the magnetic crystal grains 16a are formed before the magnetic crystal grains 16a are formed and, subsequently, the magnetic crystal grains 16a having larger grain sizes are grown while the fine crystal grains 20a serve as starting points.

Magnetic recording is conducted through magnetization of the magnetic crystal grains 16a. It is preferable that the average crystal grain size of the magnetic crystal grains 16a is 2 nm or more, and 10 nm or less in order to increase the recording density and obtain a large capacity recording medium.

It is preferable that the material for the magnetic crystal grains 16a is a ferromagnetic material having a hcp crystal structure and a Co based alloy, e.g. CoCr, CoCrTa, CoPt, CoCrPt, or CoCrPt-M, is used. As for the nonmagnetic material 16b, any nonmagnetic material which makes a solid solution with the magnetic crystal grain 16a or which does not form a compound with the magnetic crystal grain 16a can be used. As for such a nonmagnetic material, for example, oxides, e.g. SiO₂, Al₂O₃, and Ta₂O₅, nitrides, e.g. Si₃N₄, AlN, and TaN, and carbides, e.g. SiC and TaC can be used. In FIG. 1, only one layer is shown as the layer containing the magnetic crystal grains 16a and the nonmagnetic materials 16b surrounding them, although not limited to this example. A multilayer structure including at least one layer which has the above-described structure may be adopted, or a single layer structure may be adopted.

The cap layer 17 is, for example, a CoCrPt magnetic film or a CoCrB magnetic film. A carbon protective film (not shown in the drawing) and, if necessary, a lubricating layer (not shown in the drawing) may be disposed on the cap layer 17.

An example of a production process of the above-described perpendicular magnetic recording medium 10 will be described below.

First, the surface of the substrate 11 was cleaned and dried and, thereafter, a CoZrNb film 12 having a film thickness of 200 nm was formed as the soft magnetic underlayer 12 on the substrate 11. A Ta film 13 which was a single layer having a film thickness of 3 nm was formed as the orientation control layer 13 on the CoZrNb underlayer 12. Each of the CoZrNb film 12 and the Ta film 13 was formed by using a DC sputtering method in an Ar gas atmosphere. The film formation pressure was 0.5 Pa, and the film formation temperature was room temperature.

Then, the ultrathin magnetic layer 20 having a film thickness of 1.5 nm was formed on the orientation control layer 13 through room temperature deposition by the DC sputtering method at an Ar gas pressure of 7 Pa. The deposition rate was specified to be 0.5 nm/sec.

Subsequently, the first foundation layer 14 composed of Ru or a Ru alloy having a film thickness of 7.5 nm was formed through room temperature deposition by the DC sputtering method at an Ar gas pressure of 0.5 Pa. A Ru film in a continuous state was able to be formed by specifying the pressure of Ar gas to be 2 Pa or lower. The second foundation layer 15 having a film thickness of 10 nm was formed through room temperature deposition by the DC sputtering method at an Ar gas pressure of 5 Pa. The second foundation layer 15 was able to have a gap structure by controlling the deposition rate at a high pressure (5 Pa). The deposition rate at this time was 2.5 nm/sec. A good gap structure was able to be formed by specifying the deposition rate of the second foundation layer 15 to be 3 nm/sec or less. The film thicknesses of the first foundation layer 14 and the second foundation layer 15 may be specified to be 15 nm and 5 nm, respectively.

A CoCrPt—SiO₂ film having a film thickness of 1.5 nm was formed as the ultrathin magnetic layer 20 on the second foundation layer 15. The formation of the ultrathin magnetic layer 20 was conducted through room temperature deposition by the DC sputtering method at an Ar gas pressure of 7 Pa. The ultrathin magnetic layer 20 was formed by sputtering of a material in which SiO₂ is added to a CoCr based alloy. The deposition rate was 0.5 nm/sec.

The CoCrPt—SiO₂ film having a film thickness of 10 nm was formed as the recording layer 16 on the ultrathin magnetic layer 20 through room temperature deposition by the DC sputtering method at an Ar gas pressure of 3 Pa to 6 Pa. More specifically, the CoCrPt crystal grains 16a having easy magnetization axes in a direction perpendicular to the substrate 11 and SiO₂ (nonmagnetic material) 16b surrounding the CoCrPt crystal grains 16a were formed at a deposition rate of 0.5 nm/sec. The CoCrPt crystal grains 16a and the SiO₂ 16b may be formed at a higher deposition rate (e.g. 3 nm/sec) than the deposition rate of the ultrathin magnetic layer 20 because the purity of the crystal grain 16a is high and the crystal orientation dispersion of the recording layer 16 is reduced accordingly.

As described above, the desired recording layer 16 exhibiting low crystal orientation dispersion was able to be obtained by conducting formation of the ultrathin magnetic layer 20 at a relatively high (7 Pa) Ar gas pressure and conducting formation of the recording layer 16 at a relatively low (3 Pa to 6 Pa) Ar gas pressure.

Finally, a CoCrPt magnetic film having a film thickness of 5 nm was formed as the cap layer 17 through room temperature deposition by the DC sputtering method at an Ar gas pressure of 0.5 Pa and a deposition rate of 0.5 nm/sec. In the above-described series of film formation process, a vacuum environment was maintained consistently.

Effects of deposition of the ultrathin magnetic layer 20 under the recording layer 16 in the perpendicular magnetic recording medium 10 formed by the above-described film formation process will be described.

Regarding the ultrathin magnetic layer 20 and the recording layer 16, a Δθ₅₀ that is an index value indicating a degree of crystal orientation dispersion was measured. The Δθ₅₀ can be determined as a half-width of an XRD rocking curve at crystal surfaces of crystal grains. That is, the Δθ₅₀ is a value indicating variations in the orientation of a plurality of crystal surfaces.

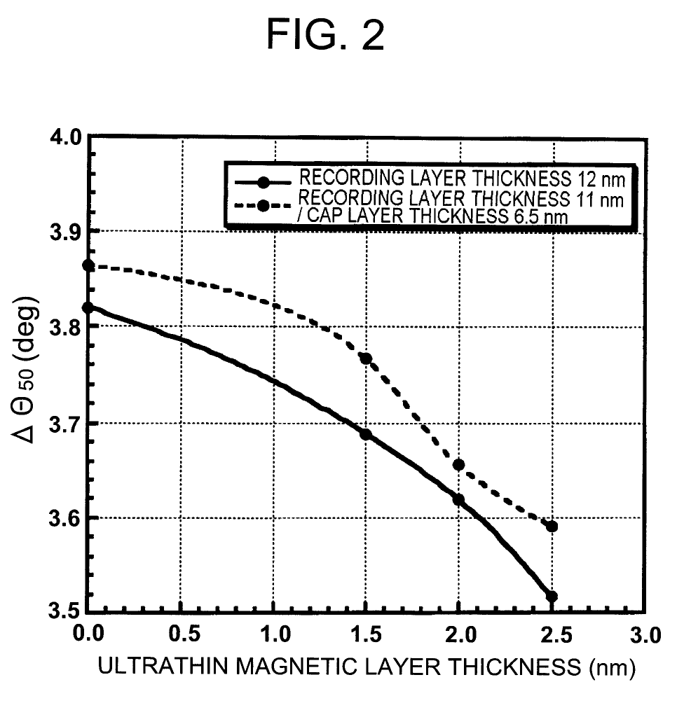

FIG. 2 is a graph showing the Δθ₅₀ of the (001) faces of the core crystal grains 20a of the ultrathin magnetic layer 20, where the thickness of the ultrathin magnetic layer 20 was changed. In the graph shown in FIG. 2, a solid line indicates the Δθ₅₀ in the case where the film thickness of the recording layer 16 was specified to be 12 nm and the cap layer 17 was not disposed. A dotted line indicates the Δθ₅₀ in the case where the film thickness of the recording layer 16 was specified to be 11 nm and the cap layer 17 having a film thickness of 6.5 nm was disposed thereon. It is clear that in each case, the Δθ₅₀ decreases as the ultrathin magnetic layer 20 become thick. It can be estimated that since the magnetic crystal grains 16a of the recording layer 16 grow on the core crystal grains 20a of the ultrathin magnetic layer 20, the Δθ₅₀ of the recording layer 16 also decreases as the Δθ₅₀ of the ultrathin magnetic layer 20 decreases.

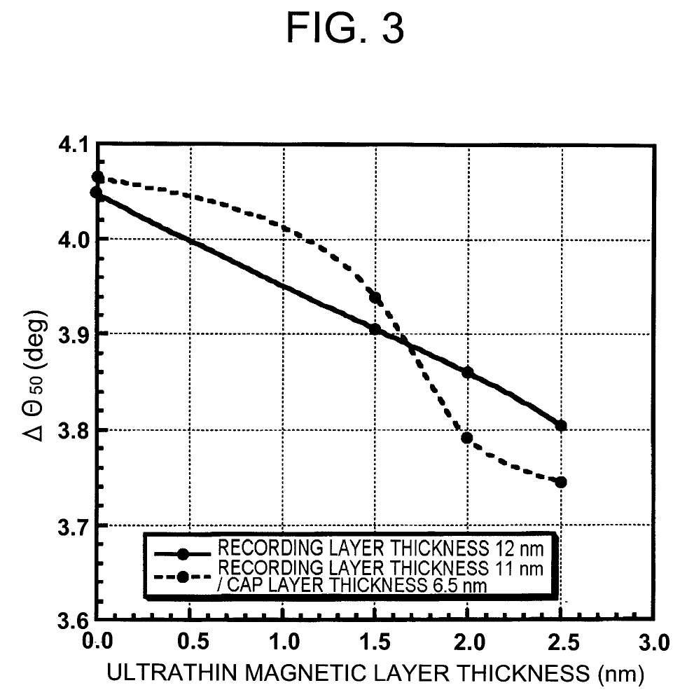

Then, the Δθ₅₀ of the recording layer 16 was determined, where the thickness of the ultrathin magnetic layer 20 was changed. FIG. 3 is a graph showing the Δθ₅₀ of the (001) faces of the magnetic crystal grains 16a of the recording layer 16, where the thickness of the ultrathin magnetic layer was changed. In the graph shown in FIG. 3, a solid line indicates the Δθ₅₀ in the case where the film thickness of the recording layer 16 was specified to be 12 nm and the cap layer 17 was not disposed. A dotted line indicates the Δθ₅₀ in the case where the film thickness of the recording layer 16 was specified to be 11 nm and the cap layer 17 having a film thickness of 6.5 nm was disposed thereon. It is clear that in each case, the Δθ₅₀ of the recording layer 16 decreases as the ultrathin magnetic layer 20 becomes thick.

Next, it was studied whether the improvement in Δθ₅₀ due to disposition of the ultrathin magnetic layer 20 contributed to the dispersion AHS of the saturation magnetic field Hs of the recording layer 16. The saturation magnetic field Hs and the dispersion ΔHs of the saturation magnetic field Hs of the recording layer 16 were measured, where the thickness of the ultrathin magnetic layer was changed.

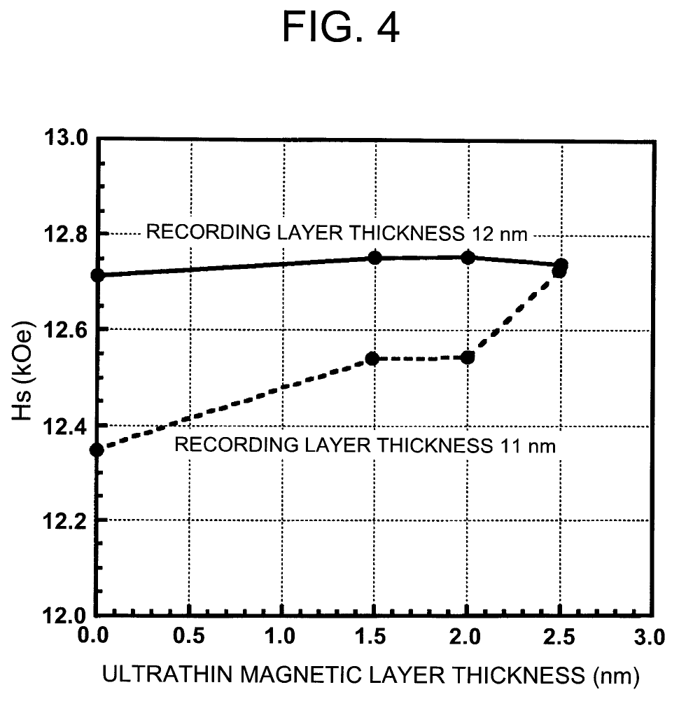

FIG. 4 is a graph showing the saturation magnetic field Hs of the recording layer 16, where the thickness of the ultrathin magnetic layer 20 was changed. In the graph, a solid line indicates the saturation magnetic field Hs in the case where the film thickness of the recording layer 16 was specified to be 12 nm. A dotted line indicates the saturation magnetic field Hs in the case where the film thickness of the recording layer 16 was specified to be 11 nm. In the case where the film thickness of the recording layer 16 is specified to be 12 nm, the saturation magnetic field Hs hardly changes even when the thickness of the ultrathin magnetic layer 20 is changed. In the case where the film thickness of the recording layer 16 is specified to be 11 nm, until the thickness of the ultrathin magnetic layer 20 reaches about 2.0 nm, the degree of increase in the saturation magnetic field Hs is small. Therefore, even if the ultrathin magnetic layer 20 is disposed, it can be said that the ultrathin magnetic layer 20 has almost no influence on the saturation magnetic field Hs insofar as the thickness thereof is 2.0 nm or less.

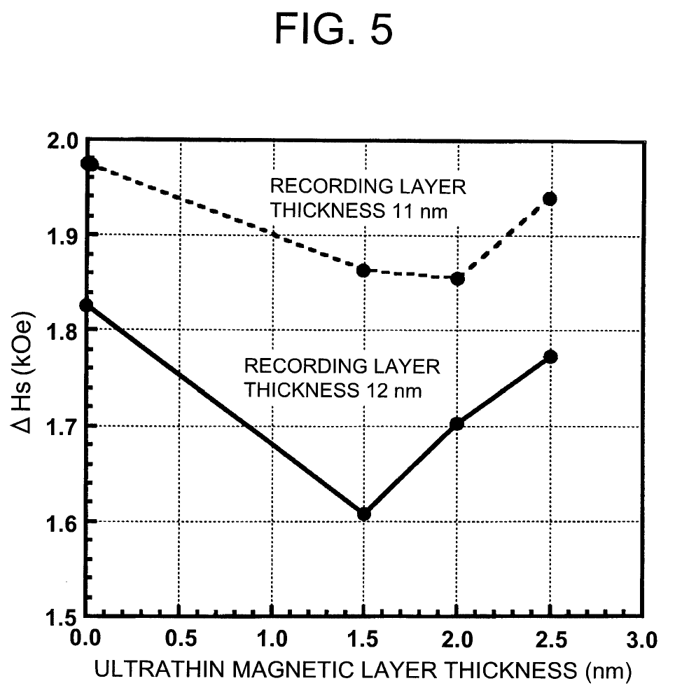

FIG. 5 is a graph showing the dispersion ΔHs of the saturation magnetic field Hs of the recording layer 16, where the thickness of the ultrathin magnetic layer was changed. In the graph, a solid line indicates the dispersion ΔHs of the saturation magnetic field Hs in the case where the film thickness of the recording layer 16 was specified to be 12 nm. A dotted line indicates the dispersion ΔHs of the saturation magnetic field Hs in the case where the film thickness of the recording layer 16 was specified to be 11 nm. In the case where the film thickness of the recording layer 16 is specified to be 12 nm, the dispersion ΔHs of the saturation magnetic field Hs becomes at a minimum when the thickness of the ultrathin magnetic layer 20 is 1.5 nm, and when the thickness of the ultrathin magnetic layer 20 reaches 2.5 nm, the dispersion ΔHs becomes almost the same as that in the case where the ultrathin magnetic layer 20 is not disposed. In the case where the film thickness of the recording layer 16 is specified to be 11 nm, the dispersion ΔHs of the saturation magnetic field Hs becomes at a minimum when the thickness of the ultrathin magnetic layer 20 is between 1.5 nm and 2.0 nm, and when the thickness of the ultrathin magnetic layer 20 reaches 2.5 nm, the dispersion ΔHs becomes almost the same as that in the case where the ultrathin magnetic layer 20 is not disposed. Therefore, it is clear that the dispersion ΔHs of the saturation magnetic field Hs can be controlled at a low level by specifying the thickness of the ultrathin magnetic layer 20 to be 2.0 nm or less.

With consideration given to the fact that if the thickness of the ultrathin magnetic layer 20 is 2.0 nm or less, the ultrathin magnetic layer 20 hardly have an influence on the saturation magnetic field Hs and the fact that the dispersion ΔHs of the saturation magnetic field Hs can be controlled at a low level by specifying the thickness of the ultrathin magnetic layer 20 to be 2.0 nm or less, it is clear that the thickness of the ultrathin magnetic layer 20 is preferably specified to be 2.0 nm or less.

On the other hand, the dispersion ΔHs of the saturation magnetic field Hs cannot be effectively controlled at a low level unless the thickness of the ultrathin magnetic layer 20 is large to some extent. As is clear from FIG. 5, if the thickness of the ultrathin magnetic layer 20 is 1.0 nm, the dispersion ΔHs of the saturation magnetic field Hs takes on a value that is substantially a median value between the minimum value and the maximum value, that is, a value when the ultrathin magnetic layer 20 is not disposed. Consequently, if the thickness of the ultrathin magnetic layer 20 is 1.0 nm or more, the dispersion ΔHs of the saturation magnetic field Hs can be effectively controlled at a low level.

In summary, it is clear that if the thickness of the ultrathin magnetic layer 20 is specified to be 1.0 nm or more, and 2.0 nm or less, the dispersion ΔHs of the saturation magnetic field Hs can be effectively controlled at a low level, and variations in magnetization characteristics of the magnetic crystal grains 16a of the recording layer 16 can be reduced.

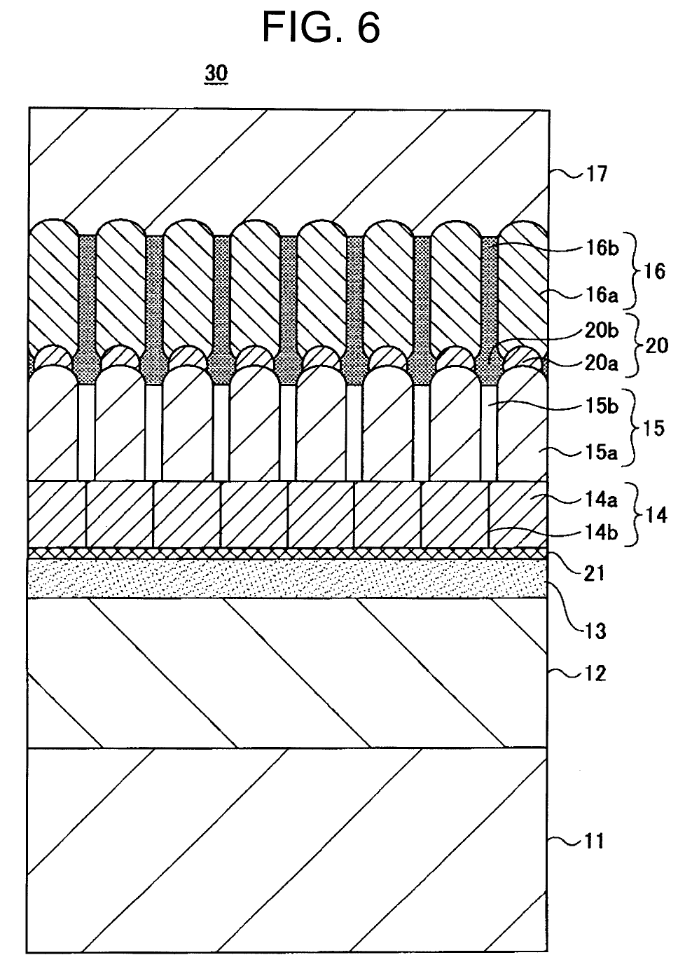

Next, a perpendicular magnetic recording medium according to a second embodiment will be described. FIG. 6 is a partial sectional view of a perpendicular magnetic recording medium 30 according to the second embodiment of the present invention. In FIG. 6, the same components as the components shown in FIG. 3 are indicated by the same reference numerals as those set forth above and further explanations thereof will not be provided.

The perpendicular magnetic recording medium 30 has nearly the same configuration as that of the above-described perpendicular magnetic recording medium 10, but is different in that a crystal structure template 21 is disposed between the orientation control layer 13 and the first foundation layer in order to control the grain size. The crystal structure template 21 is disposed to equalize grain sizes of crystal grains of a layer disposed thereon and is a film in which Ru or Ru alloy crystal structures are randomly uniformly arranged, as described later. In the present specification, such a film is referred to as a “template” for convenience.

The Ru or Ru alloy crystal structures constituting the crystal structure template 21 have a function of suppressing the dispersion of crystal grains of the layer disposed thereon. The crystal structure template 21 is a film of Ru or Ru alloy crystal structures randomly uniformly distributed on the orientation control layer 13. The Ru or Ru alloy crystal structures are smaller than the grain sizes of the first foundation layer 14, and are formed at a high density. The height of the crystal structure is 1 nm to 2 nm, and preferably 1.5 nm. The crystal structures 21a can be formed on the amorphous Ta film 13 serving as the orientation control layer 13 by using a Ru or Ru alloy target through room temperature deposition by the DC sputtering method at a high Ar gas pressure of 7 Pa to 8.5 Pa and a very small deposition rate of, for example, 0.5 nm/sec or less. In the case where the Ru or Ru alloy crystal structures 21a having heights of about 1.5 nm are formed under the above-described condition, the grain sizes of the crystal structures 21a are 2 nm or less.

By the way, disposition of the crystal structure template 21 can suppress the dispersion (variation) in grain sizes of the crystal grains of the layer disposed thereon, but the crystal orientation dispersion may deteriorate. Therefore, in the present embodiment, the ultrathin magnetic layer 20 in the above-described first embodiment is disposed above the crystal structure template 21 (specifically, on the second foundation layer 15) and, thereafter, the recording layer 16 is formed so as to improve the crystal orientation dispersion. In this manner, the grain size dispersion can be improved without deterioration of the crystal orientation dispersion.

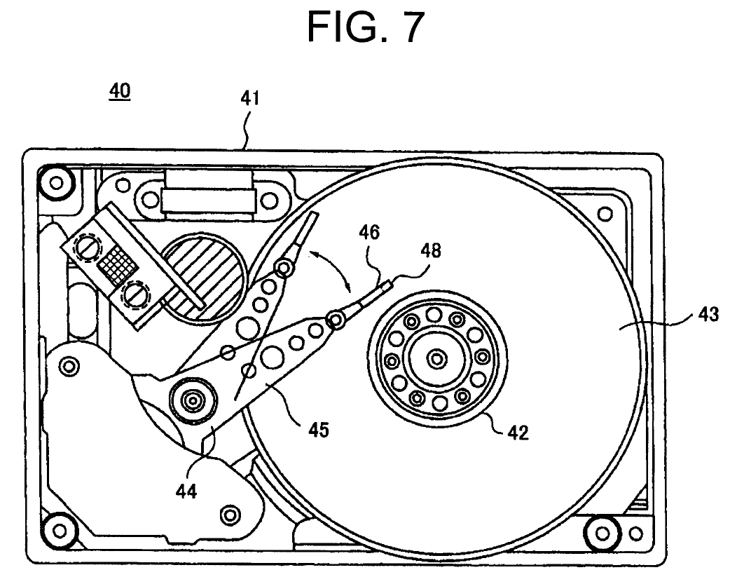

FIG. 7 is an internal plan view of a magnetic recording device, e.g. a hard disk drive, including any one of the perpendicular magnetic recording media 10 and 30 according to the first and second embodiment, respectively. The magnetic recording device 40 includes a hub 42 which is accommodated in a housing 41 and which is driven by a spindle (not shown in the drawing), a magnetic recording medium 43 which is fixed to the hub 42 and which is rotated by the spindle, an actuator unit 44, an arm 45 and a suspension 46 which are supported by the actuator unit 44 and which are driven in a radius direction of the magnetic recording medium 43, and a magnetic head 48 supported by the suspension 46. The magnetic recording medium 43 has a multistage configuration of a plurality of perpendicular magnetic recording medium 10 or 30 and magnetic heads 48 corresponding to the individual perpendicular magnetic recording media 10 or 30 are disposed. The magnetic heads 48 are included in at least a part of magnetic recording playback means, the magnetic heads 48 being capable of recording information on the recording layer 16 of the magnetic recording medium 43. Such a magnetic recording device 40 has a high S/N and a narrow write core width on a perpendicular magnetic recording medium 10 or 30 basis and, therefore, is a high performance, high recording density magnetic recording device.

According to the above-described embodiments, the crystal orientation dispersion of the second magnetic layer serving as a recording layer can be controlled within a favorable range and a high S/N ratio can be achieved. As a result, the recording density of the magnetic recording medium can be improved.

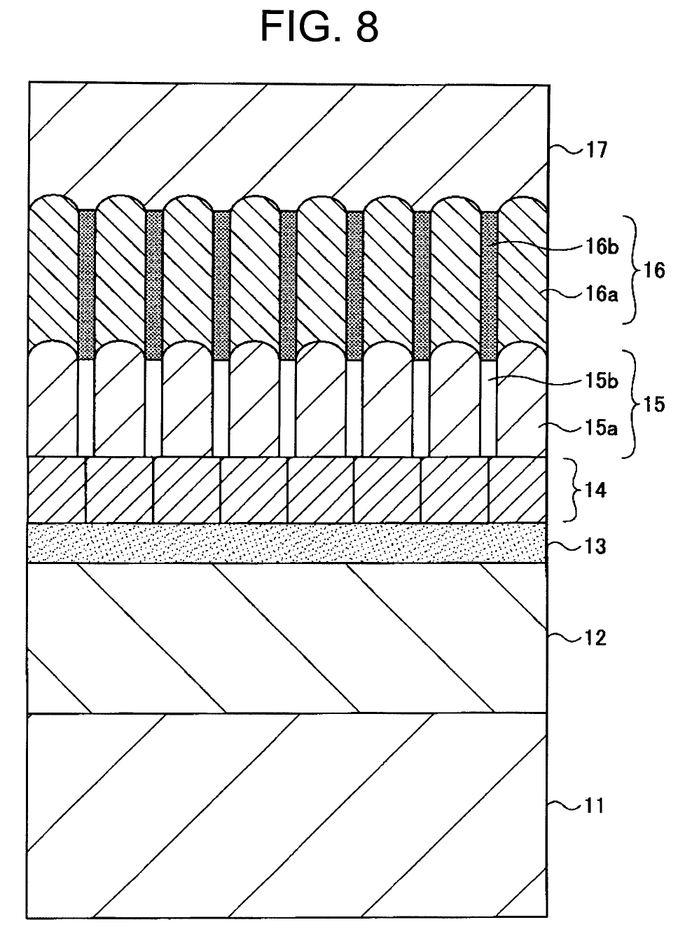

A method according to a comparative embodiment will be described, wherein, as shown in FIG. 8, a Ru foundation layer 15 serving as a substrate of a recording layer 16, which is a magnetic film, is allowed to have a gap structure in which Ru crystal grains 15a are mutually spatially separated by gap portions 15b. In the comparative embodiment shown in FIG. 8, a soft magnetic underlayer 12 and an orientation control layer 13 are disposed on a substrate 11. A first foundation layer 14 serving as a continuous layer and a second foundation layer 15 having the gap structure are disposed on the orientation control layer 13. The recording layer 16 is disposed on the second foundation layer 15. The recording layer 16 is protected by a cap layer 17. Since the second foundation layer 15 is allowed to have a gap configuration including gap portions 15b, uniform Ru crystal grain sizes in the second foundation layer 15 are inherited to a layer disposed thereon, that is, the recording layer 16. Consequently, it is possible to form a structure in which an oxide 16b that is a nonmagnetic material is filled between the magnetic crystal grains 16a of the recording layer 16 while the grain sizes of magnetic crystal grains 16a are equalized.

As in the comparative embodiment shown in FIG. 8, the second foundation layer 15 is formed from Ru crystal grains and, thereby, crystal grains 16a of the recording layer 16 can be grown on the Ru crystal grains 15a, so that isolated fine magnetic crystal grains 16a can be formed. According to this, the recording density is allowed to increase, and the amount of recording per unit volume is allowed to increase. However, in the example shown in FIG. 8, the crystal orientation of the magnetic crystal grains 16a of the recording layer 16 cannot be controlled accurately. In the example shown in FIG. 8, the (001) face of the magnetic crystal grain 16a of the recording layer 16 is an easy magnetization axis and naturally agrees with the growth direction (vertical direction in FIG. 8) of the magnetic crystal grain 16a. That is, (001) faces of the magnetic crystal grains 16a are arranged (oriented) in a direction perpendicular to the surface of the perpendicular magnetic recording medium.

However, in the case where the magnetic crystal grains 16a are merely grown on the Ru crystal grains 15a, variations (referred to as crystal orientation dispersion) may occur in orientation of the (001) faces of the magnetic crystal grains 16a. The orientation direction of the (001) face of the magnetic crystal grain 16a corresponds to the easy magnetization axis. If the orientation of the easy magnetization axis varies, variations in magnetization occur between the crystal grains 16a. Resulting from the variations in magnetization, magnetic recording characteristics may be varied between the magnetic crystal grains 16a and issues may occur in that noises may occur in reading.

In addition to variations and modifications in the component parts and/or arrangements, alternative uses will also be apparent to those skilled in the art.

What is claimed is:

1. A magnetic recording medium comprising:
a substrate;
a soft magnetic underlayer disposed on the substrate;
a foundation layer on the soft magnetic underlayer, the foundation layer including a plurality of Ru crystal grains isolated from each other at an upper portion of the foundation layer;
a first magnetic layer including a plurality of magnetic crystal grains on the plurality of the Ru crystal grains of the foundation layer; and
a second magnetic layer disposed on the plurality of magnetic crystal grains of the first magnetic layer, the second magnetic layer including a plurality of magnetic crystal grains having axes of easy magnetization in the direction perpendicular to the major surface of the substrate and nonmagnetic materials interposed between the crystal grains, the magnetic crystal grains of the first magnetic layer having a smaller grain size than those of the second magnetic layer.

2. The magnetic recording medium according to claim 1, wherein the magnetic crystal grains of the first magnetic layer include the same material as those for the magnetic crystal grains of the second magnetic layer.

3. The magnetic recording medium according to claim 2, wherein the second magnetic layer includes a material in which a metal oxide is added to a CoCrPt ternary magnetic alloy or a CoCrPt based magnetic alloy.

4. The magnetic recording medium according to claim 3, wherein the oxide is SiO₂ or TiO₂.

5. The magnetic recording medium according to claim 1, wherein the thickness of the first magnetic layer is 1 nm or more, and 2 nm or less.

6. The magnetic recording medium according to claim 1, further comprising:
a cap layer disposed on the second magnetic layer, the cap layer being made of Co alloy.

7. The magnetic recording medium according to claim 1, further comprising:
an orientation control layer formed of Ta between the soft magnetic underlayer and the foundation layer.

8. The magnetic recording medium according to claim 7, wherein the thickness of the orientation control layer is 2 nm or more.

9. The magnetic recording medium according to claim 1, wherein the distance between the magnetic crystal grains of the second magnetic layer is 2 nm or more, and 3 nm or less.

10. The magnetic recording medium according to claim 1, wherein the average grain size of the magnetic crystal grains of the second magnetic layer is 2 nm or more, and 10 nm or less.

11. The magnetic recording medium according to claim 1, wherein the Ru alloy is represented by Ru-X, where X represents at least one selected from the group consisting of Co, Cr, Fe, Ni, W. and Mn.

12. The magnetic recording medium according to claim 1, further comprising:
an orientation control layer disposed between the soft magnetic underlayer and the foundation layer, the orientation control layer having a function of distributing the magnetic crystal grains of the first and the foundation layer uniformly in an in-plane direction of the substrate.

13. The magnetic recording medium according to claim 1, further comprising:
a crystal structure film disposed under the foundation layer, the crystal structure being formed from Ru or a Ru alloy.

14. A magnetic disk device comprising:
a magnetic head for recording information; and
a magnetic recording medium for recording the information thereon, the magnetic recording medium including:
a substrate;
a soft magnetic underlayer disposed on the substrate;
a foundation layer on the soft magnetic underlayer, the foundation layer including a plurality of Ru crystal grains isolated from each other at an upper portion of the foundation layer;
a first magnetic layer including a plurality of magnetic crystal grains on the plurality of the Ru crystal grains of the foundation layer; and
a second magnetic layer disposed on the plurality of magnetic crystal grains of the first magnetic layer, the second magnetic layer including a plurality of magnetic crystal grains having axes of easy magnetization in the direction perpendicular to the major surface of the substrate and nonmagnetic materials interposed between the crystal grains, the magnetic crystal grains of the first magnetic layer having a smaller grain size than those of the second magnetic layer.

15. A method for manufacturing a magnetic recording medium comprising:
providing a substrate;
forming a foundation layer on the substrate, the foundation layer having a plurality of Ru crystal grains isolated from each other at an upper portion of the foundation layer;
forming a first magnetic layer on the foundation layer, the first magnetic layer including a plurality of magnetic crystal grains; and
forming a second magnetic layer on the first magnetic layer, the second magnetic layer including a plurality of magnetic crystal grains having axes of easy magnetization perpendicular to the substrate surface and nonmagnetic materials interposed between the magnetic crystal grains, the magnetic crystal grains of the first magnetic layer having a smaller grain size than those of the second magnetic layer.

16. The method according to claim 15, wherein formation of the first magnetic layer and the second magnetic layer is conducted by sputtering in an Ar gas atmosphere, the Ar gas pressure in formation of the first magnetic layer is higher than that of the second magnetic layer, and the deposition rate in formation of the first magnetic layer is smaller than that of the second magnetic layer.

17. The method according to claim 16, wherein the second magnetic layer is formed by sputtering of a material in which SiO₂ is added to a CoCr based alloy, and the sputtering is conducted in an Ar gas atmosphere at a pressure of 3 Pa or higher, and 6 Pa or lower.

18. The method according to claim 17, wherein the foundation layer includes a continuous layer including continuous crystal grains and a crystal grain layer including a plurality of crystal grains which are formed on the continuous layer and which are isolated from each other, and formation of the continuous layer is conducted by sputtering in an Ar gas atmosphere at a pressure of 2 Pa or lower and a deposition rate of 3 nm/sec or more.

19. The method according to claim 18, wherein formation of the crystal grain layer is conducted by sputtering in an Ar gas atmosphere at a pressure of 5 Pa or higher and a deposition rate of 2 nm/sec or less.

20. The method according to claim 15, wherein a soft magnetic underlayer is formed on the substrate before the foundation layer is formed, and the foundation layer is formed on the soft magnetic underlayer.
